(19) United States
(12) Patent Application Publication
(10) Pub. No.: US 2014/0251667 A1
(43) Pub. Date: Sep. 11, 2014

(54) Conductive Networks on Patterned Substrates

(71) Applicant: Cima Nano Tech Israel Ltd., Industrial Park Caesarea (IL)

(72) Inventors: Eric L. Granstrom, Andover, MN (US); Arkady Garbar, Lakeville, MN (US); Lorenzo Mangolini, Riverside, CA (US)

(73) Assignee: CIMA NANOTECH ISRAEL LTD., Industrial Park Caesarea (IL)

(21) Appl. No.: 14/354,321

(22) PCT Filed: Oct. 29, 2012
(86) PCT No.: PCT/IB12/02752

§ 371 Date: Apr. 25, 2014

Related U.S. Application Data
(60) Provisional application No. 61/553,192, filed on Oct. 29, 2011.

(51) Int. Cl. H05K 1/11; H05K 3/00

(52) U.S. Cl. CPC H05K 1/115; H05K 3/0094; H05K 1/09
USPC 174/257; 174/262; 427/97.7; 427/98.3; 264/400; 264/619

(57) ABSTRACT

Among other things, self-assembled conductive networks are formed on a surface of substrate containing through holes. The conductive network having a pattern is formed such that at least some of the conductive material in the conductive network reaches into the holes and, sometimes, even the opposite surface of the substrate through the holes. The network on the surface of the substrate electrically connects to the conductive material in the holes with good conductance.

### CROSS-REFERENCE TO RELATED APPLICATIONS

This application claims priority to U.S. Provisional Application Ser. No. 61/553,192, filed on Oct. 29, 2011, the content of which is incorporated herein in its entirety.

### TECHNICAL FIELD

This disclosure relates to conductive networks on patterned substrates, particularly, self-assembled conductive networks on substrates containing through holes.

### BACKGROUND

In the field of photovoltaics, high performance solar cell efficiency requires multiple and expensive processing steps to fabricate desired features in the solar cell. Such steps limit the utility of solar cells owing to added process costs.

In conventional solar cell designs, photogenerated current is driven to two electrodes: (1) a bottom (often continuous and uniform) electrode on a bottom side of the solar cell and (2) a fine printed array of wires on a front side (illuminated side) opposite to the bottom side. The fine printed array of wires on the front side of the solar cell can be formed by screen printing silver pastes into a fine pattern of lines. Improvements in the performance of solar cells (e.g., Watts generated per unit area), for example, by improving the patterning of the electrodes on a solar cell, are sought.

There has been a desire to improve the performance of a solar cell by reducing the printed silver area on the front side of the solar cell. Reduced areas of silver allow more light to enter the photoactive portions of the solar cell, thus improving efficiency. Metal-wrap-through (MWT) designs have been described as a way of achieving this, in which electrical contacts between the front and bottom sides of the solar cell are made using through-silicon-vias (TSVs).

There would be benefits from improved ways of forming conductive networks on and through solar cells. More generally, there would be benefits from improved ways of forming conductive networks on and through film substrates, including applications in other photovoltaic (e.g., thin film photovoltaics) applications, and electronics applications more generally (including transparent electrode applications for flat panel displays, transparent heaters, lighting, and etc.).

### SUMMARY

In one aspect, the disclosure features self-assembled conductive networks on a surface of substrate containing through holes. The conductive network having a pattern is formed such that at least some of the conductive material in the conductive network reaches into the holes and, sometimes, even the opposite surface of the substrate through the holes. The conductive material is formed in the holes while the conductive network is formed on the surface of the substrate. The network on the surface of the substrate electrically connects to the conductive material in the holes with good conductance. In some implementations, currents collected by the conductive network on the surface of the substrate can be directed through the conductive material in the holes to the opposite side of the substrate. Such substrates can be used in photovoltaic cells, such as cells having the metal-wrap-through (MWT) designs. The one-step formation (e.g., by self-assembling) of the conductive network and conductive materials within the holes or even on the second surface can simplify manufacturing processes, improve process throughput, and reduce cost, while providing good conductance between the surface and the holes, and between the surface and the opposite side of the surface.

In another aspect, the disclosure features an article comprising a substrate, a conductive material, and a self-assembled conductive network. The substrate comprises a first surface, a second surface, a thickness from the first surface to the second surface, and one or more holes extending through the thickness of the substrate. The conductive material is within the one or more holes. The self-assembled conductive network is on the first surface and comprises the conductive material. The self-assembled conductive network is in electrical communication with the conductive material within the one or more holes.

In another aspect, the disclosure features a method comprising providing a substrate comprising a first surface, a second surface, a thickness from the first surface to the second surface, and one or more holes extending through the thickness of the substrate; and applying an emulsion and a non-volatile component dispersed in the emulsion on the first surface of the substrate. The emulsion and the non-volatile component self-assemble into a conductive network on the first surface of the substrate and a conductive material in the one or more holes. The conductive network and the conductive material are in electrical communication to direct electrical current from the first surface, through the one or more holes, towards the second surface.

The disclosure also features one or more of the following embodiments. The self-assembled conductive network extends into the one or more holes and the conductive material in the one or more holes is an extended portion of the self-assembled conductive network. The self-assembled conductive network extends through the one or more holes and onto the second surface. The conductive material within the one or more holes and the self-assembled conductive network are in electrical communication to direct electrical current from the first surface to the second surface. The self-assembled conductive network has a first anisotropy remote from the one or more holes and a second anisotropy adjacent the one or more holes, wherein the second anisotropy is higher than the first anisotropy. The self-assembled conductive network is isotropic remote from the one or more holes. The self-assembled conductive network comprises metal traces and pores among the traces, and the metal traces adjacent the one or more holes extend towards and into the one or more holes in a radial pattern. The self-assembled conductive network is formed from metal nanoparticles. The metal nanoparticles comprise silver nanoparticles. The substrate comprises a semiconductor, a polymeric film, or glass. The one or more holes are formed by laser drilling or etching.

The disclosure also features one or more of the following embodiments. The conductive material in the one or more holes is an extended part of the conductive network and is formed during the self-assembly of the conductive network. The emulsion and the non-volatile component self-assemble into a conductive network that extends through the one or more holes and onto the second surface. The one or more holes in the substrate is formed by laser drilling or etching. The emulsion comprises a water-in-oil emulsion or an oil-in-water emulsion. The non-volatile component comprises metal or ceramic nanoparticles. Self-assembling a conductive network comprises forming a conductive network having a low anisotropy remote from the one or more holes and a high anisotropy adjacent the one or more holes. Forming a conductive network having a high anisotropy adjacent the one or more holes comprises forming metal traces extending towards and into the one or more holes in a radial pattern. The conductive network is sintered.

Other features, objects, and advantages will be apparent from the description and drawings.

### DESCRIPTION OF DRAWINGS

FIG. 1 is a micrograph of a conductive network on a surface of a substrate.

FIGS. 2, 3A, 3B, and 4 are micrographs of conductive networks on surfaces of substrates containing through holes.

FIG. 5A is a schematic view of a conductive network on a substrate containing through holes.

FIG. 5B is a schematic view of a substrate containing through holes arranged in a pattern.

FIG. 5C is a schematic view of a random conductive network on a surface of a substrate containing through holes.

FIG. 5D is a schematic view of a conductive network having features of this disclosure on a surface of a substrate containing through holes.

### DETAILED DESCRIPTION

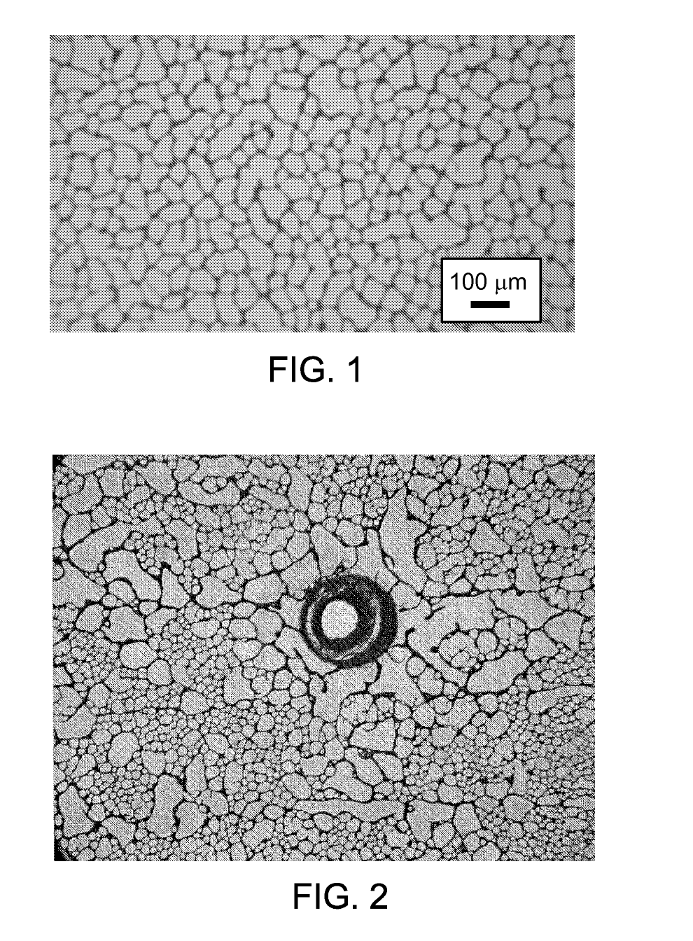

In some implementations, self-organizing properties of emulsions can be used advantageously to make useful patterns on surfaces, including the fabrication of random metal meshes. Such random metal meshes may also be of use in photovoltaics cells. As an example, FIG. 1 shows a micrograph of such a metal mesh, where dark areas are silver traces and light areas are non-conductive, light-transmissive voids or pores among the traces. Random metal meshes are described in U.S. Pat. No. 7,601,406, and the use of such meshes in photovoltaic cells is described in U.S. Patent Application Publication No. 2011/0175065, the entire contents of both are incorporated herein by reference.

A self-organizing coating material including an emulsion or a foam (e.g. a liquid phase intermixed with a gas) is used to form transparent, conductive networks on substrates having holes or vias. For example, the transparent, conductive networks can be front electrodes on solar cells having TSVs. Such processes have advantages over processes used for generating random metal meshes because these processes can produce specific advantageous network patterns around and/or through the holes by self-organization. In particular, the network patterns around and/or through the holes and the network patterns remote from the holes can be self-organized within one step. The emulsion or foam penetrates the holes to form, in the holes, a conductive material as an extended portion of the network patterns on the surface in which the holes are defined.

Whereas a random mesh conductor will have only nominally isotropic sheet resistance, a more optimized, non-homogeneous mesh pattern may be useful to produce directionality (anisotropy) to such a conductive mesh at electrical current concentration points, such as holes or vias.

The preferred patterns (e.g., conductive networks) may be formed (e.g. self-assembled) owing to direct interaction between the emulsion and substrate. The substrates, coating materials, and processes can have the following features.

Substrates—A variety of unpatterned substrates can be used. If the objective is to prepare an article having a transparent, conductive coating, the substrate preferably is substantially transparent to light in the visible region (400-800 nm). Examples of suitable substrates include glass, polymeric materials (e.g., polymethylmethacrylate, polyethylene, polyethylene terephthalate, polypropylene, or polycarbonate), ceramics (e.g., transparent metal oxides), and semiconductive materials (e.g., silicon or germanium). The substrate may be used as is or pre-treated to alter its surface properties. For example, the substrate may be pre-treated to improve adhesion between the coating and the substrate surface, or to increase or control the surface energy of the substrate. Both physical and chemical pre-treatments can be used. Examples of physical pre-treatments include corona, plasma, ultraviolet, thermal, or flame treatment. Examples of chemical pre-treatments include etchants (e.g., acid etchants), primers, anti-reflection coatings, or hard-coat layers (e.g., to provide scratch-resistance). In particular, the substrate can be a substrate, e.g., a semiconductive substrate, containing photovoltaic cell.

The substrates can also be patterned substrates. For example, the unpatterned substrates can be patterned before the transparent, conductive coating applied to the substrates. In some implementations, a semiconductive substrate can be patterned to form through holes, e.g., using laser drilling or etching. In some implementations, the substrate can be a substrate containing a first random network formed based on an emulsion, before the substrate is patterned or used in forming the conductive network. Examples of formation of the first random network are discussed in Attorney Docket No. 17709-0031P01, filed on the same day as the present application and the entire content of which is incorporated herein by reference.

Coating materials—Suitable coating materials for use can include a non-volatile component and a liquid carrier. The liquid carrier is in the form of an emulsion having a continuous phase and domains dispersed in the continuous phase.

Examples of suitable non-volatile components include metal and ceramic nanoparticles. The nanoparticles preferably have a D₉₀ value less than about 100 nanometers. Specific examples include metal nanoparticles prepared according to the process described in U.S. Pat. No. 5,476,535 and U.S. Pat. No. 7,544,229, both of which are incorporated by reference in their entirety. As described in these two patents, the nanoparticles are generally prepared by forming an alloy between two metals; such as an alloy between silver and aluminum, leaching one of the metals, such as the aluminum, using a basic or acidic leaching agent to form a porous metal agglomerate; and then disintegrating the agglomerate (e.g., using a mechanical disperser, a mechanical homogenizer, an ultrasonic homogenizer, or a milling device) to form nanoparticles. The nanoparticles may be coated prior to disintegration to inhibit agglomeration. In some implementations, the particles can be larger than nano-sized. Materials for nano-sized or larger particles can also include glass frit.

Examples of useful metals for making the nanoparticles include silver, gold, platinum, palladium, nickel, cobalt, copper, titanium, iridium, aluminum, zinc, magnesium, tin, and combinations thereof. Examples of useful materials for coating the nanoparticles to inhibit agglomeration include sorbitan esters, polyoxyethylene esters, alcohols, glycerin, polyglycols, organic acid, organic acid salts, organic acid esters, thiols, phosphines, low molecular weight polymers, and combinations thereof.

The concentration of the non-volatile component (e.g., nanoparticles) in the liquid carrier generally ranges from about 1-50 wt %, preferably 1-10 wt %. The specific amount is selected to yield a composition that may be coated on the substrate surface. When an electrically conductive coating is desired, the amount is selected to yield an appropriate level of conductivity in the dried coating.

The liquid carrier is in the form of an emulsion featuring a continuous phase and domains dispersed in the continuous phase. In some implementations, the emulsion is a water-in-oil (W/O) emulsion in which one or more organic liquids form the continuous phase and one or more aqueous liquids form the dispersed domains. In other implementations, the emulsion is an oil-in-water (O/W) emulsion in which one or more aqueous liquids form the continuous phase and one or more organic liquids form the dispersed domains. In both cases, the aqueous and organic liquids are substantially immiscible in each other such that two distinct phases are formed.

Examples of suitable aqueous liquids for either a W/O or O/W emulsion include water, methanol, ethanol, ethylene glycol, glycerol, dimethyformamide, dimethylacetamide, acetonitrile, dimethylsulfoxide, N-methylpyrrolidone, and combinations thereof. Examples of suitable organic liquids for either a W/O or O/W emulsion include petroleum ether, hexanes, heptanes, toluene, benzene, dichloroethane, trichloroethylene, chloroform, dichloromethane, nitromethane, dibromomethane, cyclopentanone, cyclohexanone, and combinations thereof. Solvents should be selected so that the solvent of the continuous phase of the emulsion evaporates faster than the solvent of the dispersed domains. For example, in some implementations, the emulsion is a W/O emulsion where the organic liquid evaporates more quickly than the aqueous liquid.

The liquid carrier may also contain other additives. Specific examples include reactive or non-reactive diluents, oxygen scavengers, hard coat components, inhibitors, stabilizers, colorants, pigments, IR absorbers, surfactants, wetting agents, leveling agents, flow control agents, rheology modifiers, slip agents, dispersion aids, defoamers, binders, adhesion promoters, corrosion inhibitors, and combinations thereof.

In some embodiments, the coating material can have a nonvolatile element in a liquid phase intermixed with a gas, such as in the form of a foam. In a preferred embodiment, the nonvolatile element is metal nanoparticles. The metal particles may be dispersed in a water based liquid dispersion and mixed with air to form a foam. In some embodiments, such a dispersion is aqueous and there is no need for immiscible organic solvents and an emulsion. Such a coating material is described in U.S. Patent Application Publication No. 2011/0193032, the entire content of which is incorporated herein by reference.

Process—Suitable coating processes can include screen-printing, manual applicator and manual spreading. Other suitable techniques such as spin coating, spray coating, ink jet printing, offset printing, Mayer rod coating, gravure coating, microgravure coating, curtain coating, and any suitable technique can also be used. After the coating material is applied, the solvent is evaporated from the emulsion, with or without the application of temperatures above ambient. Preferably, the remaining coating is sintered at a temperature within the range of about room temperature to about 850° C. Sintering preferably takes place at ambient atmospheric pressure.

Alternatively or additionally, all or part of the sintering process can take place in the presence of a chemical that induces the sintering process. Examples of suitable chemicals include formaldehyde or acids, such as formic acid, acetic acid, and hydrochloric acid. The chemical may be in the form of a vapor or a liquid to which the deposited particles are exposed. Alternatively, such chemicals may be incorporated into the composition comprising the nanoparticles prior to deposition, or may be deposited on the nanoparticles after depositing the particles on the substrate.

The process may also include a post-sintering treatment step, in which the formed conductive layer may be further sintered, annealed, or otherwise post-treated using thermal, laser, UV, acid or other treatments and/or exposure to chemicals such as metal salts, bases, or ionic liquids. The treated conductive layer may be washed with water or other chemical wash solutions such as acid solution, acetone, or other suitable liquids. Post-treatment of the coating can be performed by batch process equipment or continuous coating equipment, on small laboratory scales or on larger industrial scales, including roll-to-roll processes.

Suitable substrates, coating materials, and processes, and self-assembling processes are also described in U.S. patent application Ser. No. 12/809,195 (filed on Jul. 26, 2011), U.S. Provisional Application No. 61/495,582 (filed on Jun. 10, 2011), and U.S. Pat. No. 7,566,360, the entire contents of which are incorporated herein by reference.

### EXAMPLES

### Example 1

The primer-treated side of a 4 mil Mitsubishi E100 polyethylene terephthalate (PET) substrate (Mitsubishi Polyester Film, Mitsubishi, Japan) was used.

The substrate was prepared by laser drilling to form holes having a diameter of approximately 100 μm (i.e., vias) through the thickness of the PET substrate. An Epilog Mini 24 30W laser system (Golden, Colorado) was used, and the holes were formed in a square pattern with approximate 1 inch spacing.

A coating material including an emulsion having the composition (quantities in grams) shown in Table 1 was mixed by sonication for 40 seconds at 40 W using a Misonix 3000 sonicating mixer in a beaker.

TABLE 1

| | |
|---|---|
| Byk410 (rheological agent | 0.078 |
| including a modified urea, BYK-Chemie | |
| GmbH, Wesel, Germany) | |
| Span 60 (sorbitan | 0.064 |
| monooctadecanoate, Sigma-Aldrich Co.) | |
| Cyclohexanone (Sigma-Aldrich | 2.288 |
| Co.) | |
| Silver Nanoparticle Powder P204 | 2.017 |
| (Cima NanoTech, Inc., Caesarea, Israel) | |
| Toluene (VWR Industries, Batavia, | 25.253 |
| Illinois) | |
| 5 wt % Q4-3667 in toluene (Dow | 0.294 |
| Corning, Midland, Michigan) | |
| 5 wt % Ethyl Cellulose in Toluene | 0.352 |
| (Sigma Aldrich) | |
| 1 wt % SYNPERONIC NP-30 in | 0.214 |
| toluene (a polyethylene glycol nonylphenyl | |
| ether, Fluka, Gillingham, England) | |
| 2-Amino-1-Butanol (Sigma Aldrich | 0.064 |
| Co.) | |
| Aniline (Fluka, St. Gallen | 0.037 |
| Switzerland) | |
| Cymel 303 (Cytec Industries West | 0.072 |
| Paterson, NJ) | |
| Kflex A307 (Kings Industries, | 0.085 |
| Norwalk, CT) | |
| Nacure 2501 (Kings Industries, | 0.143 |
| Norwalk, CT) | |

To that dispersion, the following material in Table 2 was added (quantities in grams), and was mixed with the other materials by 2 cycles of sonication for 30 seconds each cycle, with a 30 second interval to allow pipette-based remixing. Sonication was at 40 W using a Misonix 3000 sonicating mixer in a beaker.

TABLE 2

| | |
|---|---|
| 0.02% BYK 348 in water (Byk 348, a | 19.035 |
| polyether modified siloxane wetting agent, | |
| being supplied by BYK-Chemie GmbH, | |
| Wesel, Germany) | |

The coating material was applied in excess by pipette to one end of a 4″×4″ piece of the prepared PET substrate and drawn down by a Mayer rod giving a nominal 30 micron thickness coating. The applied coating material was then dried in a 50° C. oven for 1 minute immediately after coating.

FIG. 2 shows a micrograph of the resultant coating with one of the 100 μm holes visible in the center, and portions of two more holes visible at the upper and lower left corners of the micrograph. The light colored areas are light-transmissive cells or voids in the network containing no silver, while the dark lines are the conductive silver network traces.

As can be seen in the figure, there is a different network pattern formation remote from the hole relative to proximal to the hole. Small network structure with low anisotropy is present away from the via hole. In particular, near the hole, silver traces aggregate to form higher metal content lines, and there is increased directionality in such lines (directing towards the hole). It can be seen that the metal traces on the surface are electrically contacting the via hole (note the presence of fine metal contact lines inside the rim of the hole). Away from the hole, the network structure can be isotropic.

Transparency (or transmittance) and sheet resistance of the coating were tested based on the following methods:

% Transmittance (% T)

% Transmittance is the average percent of light that is transmitted through a sample at wavelengths between 400-740 nm with a 20 nm resolution as measured by a GretagMacbeth Color Eye 3000 Spectrophotometer with an integrated sphere (X-rite Corp, Grand Rapids, Mich.).

Sheet Resistance (Rs)

Sheet resistance was measured using a Loresta-GP MCP T610 4 point probe (Mitsubishi Chemical, Chesapeake, Va.).

The tested results showed that transparency remote from the via hole was approximately 67.5%, and the sheet resistance was approximately 8 Ohms/sq.

### Example 2

A second coated film/substrate was made according to Example 1, except that the coated film/substrate was allowed to dry more slowly by leaving the film/substrate at room temperature during pattern formation, rather than drying in an oven.

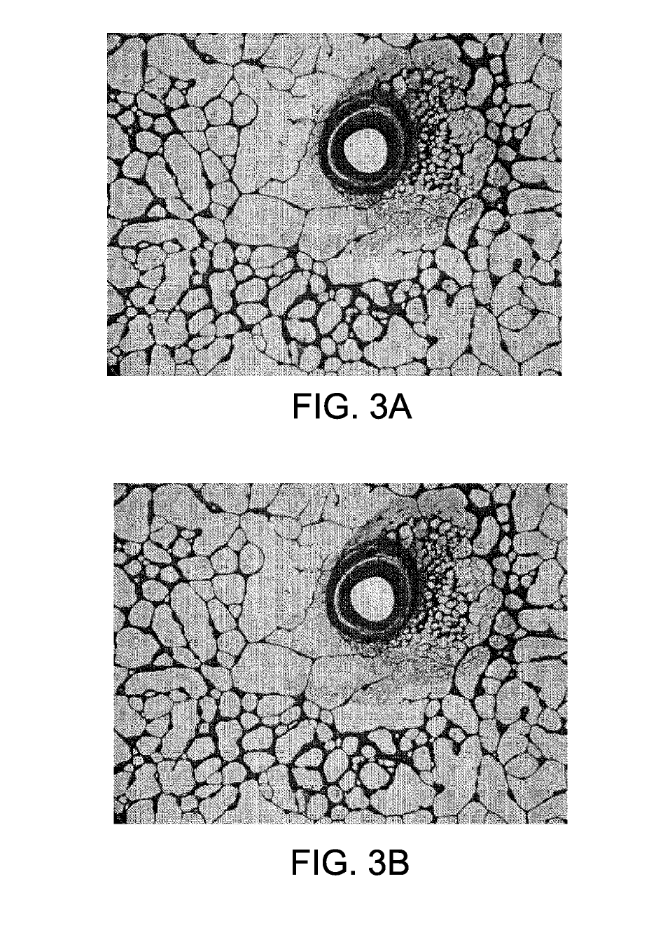

A micrograph of the resulting coated film is shown in FIGS. 3(A) and 3(B), which illustrates a visible hole in the center. FIG. 3(A) is a reflected light image. FIG. 3(B) is a transmitted light image.

In this case, the coating material was capable of penetrating into and through the via to the rear (or bottom) side of the film prior to completion of drying and pattern formation. In the small pore size network, the denser and darker “smear” of material near the via/hole is material (i.e., silver) on the rear side of the via (as evidenced by the difference in focal depth and contrast in reflected/transmitted light). The larger pore size network distant from the via/hole is on the front side onto which the coating material is applied.

### Example 3

A third coated film/substrate was made according to Example 1, with the following changes. The prepared coating material was left uncovered in a beaker overnight at ambient lab conditions, and then remixed gently by pipette immediately prior to coating. Additionally, the coating was applied by Mayer rod at a nominal thickness of 60 μm.

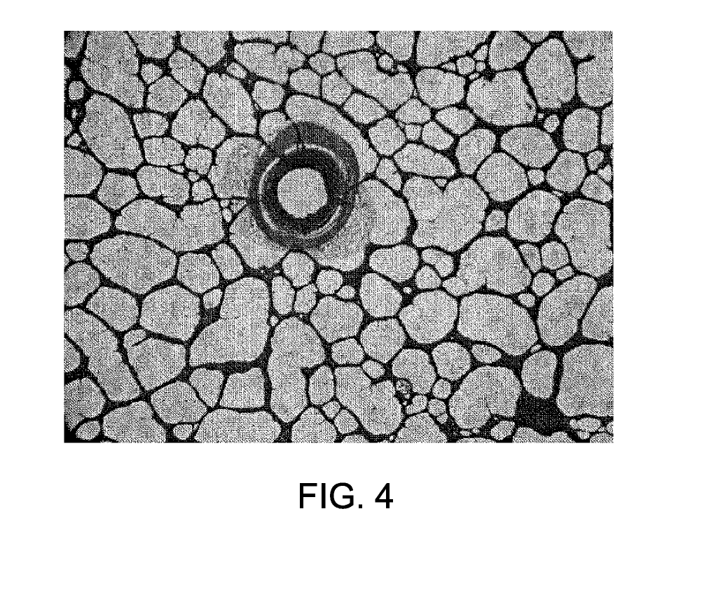

A micrograph of the resulting coating is shown in FIG. 4 with one of the 100 μm holes visible in the center. In this example, there is less non-homogeneity in the conductive network. However the conductive silver is clearly visible as having penetrated into and through the hole, causing the concentric dark colored area to be shown through the transparent film/substrate. The silver traces are also clearly shown to extend to and into the hole in a radial pattern.

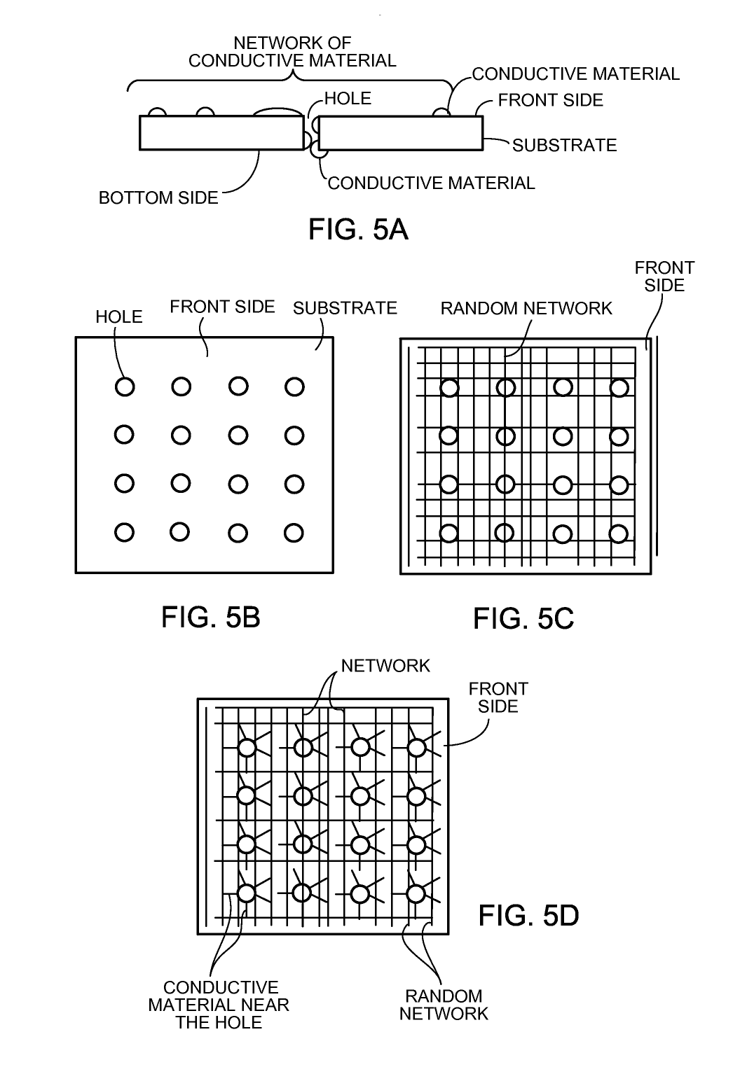

Referring to FIGS. 5A, 5B, and 5D, a network of conductive material is formed on a front side of a substrate. The substrate includes patterned micron-sized through holes, and the conductive material reaches and wets the holes. Some of the conductive material reaches the bottom side of the substrate.

Referring to FIG. 5C, when the coating material forms a transparent conductive coating having a random network (here drawn as rectangles, but in general the network can be random), there is no concentration of the conductive material and no anisotropy pulling current towards the vias/holes. In contrast, the self-assembled network shown in FIG. 5D has a preferred structure, with a random network in background and concentrated conductive material near the holes/vias. The conductive material near the holes/vias electrically contacts the holes/vias and extends into the holes/vias. The conductive material near the holes/vias is aligned better than in the random network (anisotropy). A high conductance is provided near the holes/vias.

1. An article comprising:
a substrate comprising a first surface, a second surface, a thickness from the first surface to the second surface, and one or more holes extending through the thickness of the substrate;
a conductive material within the one or more holes; and
a self-assembled conductive network on the first surface, the self-assembled conductive network comprising the conductive material and being in electrical communication with the conductive material within the one or more holes.

2. The article of claim 1, wherein the self-assembled conductive network extends into the one or more holes and the conductive material in the one or more holes is an extended portion of the self-assembled conductive network.

3. The article of claim 2, wherein the self-assembled conductive network extends through the one or more holes and onto the second surface.

4. The article of claim 1, wherein the conductive material within the one or more holes and the self-assembled conductive network are in electrical communication to direct electrical current from the first surface to the second surface.

5. The article of claim 1, wherein the self-assembled conductive network has a first anisotropy remote from the one or more holes and a second anisotropy adjacent the one or more holes, the second anisotropy being higher than the first anisotropy.

6. The article of claim 5, wherein the self-assembled conductive network is isotropic remote from the one or more holes.

7. The article of claim 5, wherein the self-assembled conductive network comprises metal traces and pores among the traces, and the metal traces adjacent the one or more holes extend towards and into the one or more holes in a radial pattern.

8. The article of claim 1, wherein the self-assembled conductive network is formed from metal nanoparticles.

9. The article of claim 8, wherein the metal nanoparticles comprise silver nanoparticles.

10. The article of claim 1, wherein the substrate comprises a semiconductor, a polymeric film, or glass.

11. The article of claim 1, wherein the one or more holes are formed by laser drilling or etching.

12. A method comprising:
providing a substrate comprising a first surface, a second surface, a thickness from the first surface to the second surface, and one or more holes extending through the thickness of the substrate; and
applying an emulsion and a non-volatile component dispersed in the emulsion on the first surface of the substrate, wherein the emulsion and the non-volatile component self-assemble into a conductive network on the first surface of the substrate and a conductive material in the one or more holes, the conductive network and the conductive material being in electrical communication to direct electrical current from the first surface, through the one or more holes, towards the second surface.

13. The method of claim 12, wherein the conductive material in the one or more holes is an extended part of the conductive network and is formed during the self-assembly of the conductive network on the first surface.

14. The method of claim 12, wherein the emulsion and the non-volatile component self-assemble into a conductive network that extends through the one or more holes and onto the second surface.

15. The method of claim 12, further comprising forming the one or more holes in the substrate by laser drilling or etching.

16. The method of claim 12, wherein the emulsion comprises a water-in-oil emulsion or an oil-in-water emulsion.

17. The method of claim 12, wherein the non-volatile component comprises metal or ceramic nanoparticles.

18. The method of claim 12, wherein self-assembling into a conductive network comprising forming a conductive network having a low anisotropy remote from the one or more holes and a high anisotropy adjacent the one or more holes.

19. The method of claim 18, wherein forming a conductive network having a high anisotropy adjacent the one or more holes comprises forming metal traces extending towards and into the one or more holes in a radial pattern.

20. The method of claim 12, further comprising sintering the conductive network.
